(19) United States
(12) Patent Application Publication
(10) Pub. No.: US 2003/0017708 A1
(43) Pub. Date: Jan. 23, 2003

(54) Plasma etching gas

(76) Inventor: Ming-Chung Liang, Taipei (TW)

Correspondence Address: J.C. Patents, Inc., Suite 250, 4 Venture, Irvine, CA, 92618, US

(21) Appl. No.: 09/974,582

(22) Filed: Oct. 9, 2001

(30) Foreign Application Priority Data
Jul. 6, 2001 (TW) 90116538

(51) Int. Cl. H01L 21/311; H01L 21/302; H01L 21/461

(52) U.S. Cl. 438/700

(57) ABSTRACT

A plasma etching gas, suitable for etching the silicon layer in a silicon oxide etching device. The plasma etching gas can be a fluoroalkane gas, such as fully fluoro-substituted alkane gas and a partially fluoro-substituted alkane gas, an argon gas or a nitrogen gas. The ratio of the partially fluoro-substituted alkane to the fully fluoro-substituted alkane in the plasma etching gas is about 3/1 to about 15/1.

### CROSS-REFERENCE TO RELATED APPLICATION

This application claims the priority benefit of Taiwan application serial no. 90116538, filed Jul. 6, 2001.

### BACKGROUND OF THE INVENTION

1. Field of the Invention

The present invention relates to a process for etching an integrated circuit. More specifically, the present invention relates to a plasma etching gas used for the etching process.

2. Description of Prior Art

Minimization and high integration of semiconductor devices has been the goal in the semiconductor industry. An etching process and a photolithography process are considered key points to success. The etching process includes a wet etching process and a dry etching process. The dry etching process has advantages over the wet etching process such as lower cost, higher yield and anisotropy, and has consequently become a necessary technology for the semiconductor process.

Currently, silicon substrate is commonly used as a semiconductor substrate. The silicon layer is etched in a silicon oxide etching device while etching a silicon oxide. The etching gas used is a mixed gas of trifluoro-methane (CHF₃), tetrafluoro-methane and argon. Since the fluoro-alkane (CxHyFz) tends to be deposited on the silicon layer to form a polymer layer having an undesirable thickness, the etching uniformity of the silicon layer is poor.

One attempt has been made to add oxygen gas in the above etching gas. The oxygen reacts with the tetrafluoro-methane in the etching gas to form carbon monoxide or carbon dioxide that consumes the carbon atoms in the plasma etching gas. Therefore, the polymer layer deposited on the silicon layer decreases and the etching uniformity of the silicon layer can be improved. However, oxygen also consumes photoresists made of organics, resulting in a deteriorated etching critical dimension (ECD).

### SUMMARY OF THE INVENTION

It is one object of the present invention to provide a plasma etching gas that can greatly improve the etching uniformity for a silicon layer, while preventing the etching critical dimension from being affected by overloading of a photoresist.

In one aspect of the present invention, the plasma etching gas can be used to etch the silicon layer in a silicon oxide etching device. The plasma etching gas of the present invention includes a fully fluoro-substituted alkane gas, a partially fluoro-substituted alkane gas, an argon gas and a nitrogen gas.

The ratio of the partially fluoro-substituted alkane to the fully fluoro-substituted alkane in the plasma etching gas is about 3/1 to about 15/1. The flow rate of the nitrogen gas is about 1 sccm to about 50 sccm. The flow rate of the argon gas is about 50 sccm to 150 sccm. The etching device is operated under about 110 mtorr to about 200 mtorr of pressure and about 500 w to about 700 w of power.

It is another object of the present invention to provide a plasma etching gas suitable for etching a silicon substrate in a silicon oxide etching device. The plasma etching gas includes a fluoro-alkane gas and a nitrogen gas.

Fluoro-alkane gas would be selected from tetrafluoro-methane (CF₄), hexafluoro-ethane (C₂F₆), octfluoro-propane (C₃F₈), octfluoro-butane (C₄F₈), monofluoro-methane (CH₃F), trifluoro-methane (CHF₃) or difluoro-methane (CH₂F₂). The plasma etching gas could further include an argon gas.

It is important for the present invention to add the nitrogen gas into the plasma etching gas for etching the silicon oxide and the silicon substrate. The nitrogen gas makes polymers deposited onto the silicon layer puffy such that the plasma is allowed to efficiently penetrate through the polymer and to etch the silicon layer. This approach increases the etching uniformity with respect to the silicon layer, while preventing the etching critical dimension from being affected by overloading of a photoresist mask.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIGS. 1A-1C are schematic flow charts showing one preferred embodiment of the present invention.

### DESCIPTION OF THE PREFERRED EMBODIMENT

Reference will now be made in detail to the present preferred embodiments of the invention, examples of which are illustrated in the accompanying drawings. Whenever possible, the same reference numbers are used in the drawings and the description to refer to the same or like parts.

In one preferred embodiment of the present invention, the plasma etching gas for etching silicon layer contains nitrogen gas, which makes polymers deposited onto the silicon layer puffy such that the plasma is allowed to efficiently penetrate through the polymer and to etch the silicon layer. This approach increases the etching uniformity with respect to the silicon layer, while preventing the etching critical dimension from being affected by overloading of a photoresist mask. The amount of the nitrogen gas contained in the plasma etching gas of the present invention can be about 1 sccm to 50 sccm.

In an etching device used for etching silicon oxide, an etching gas used to etching the silicon oxide and silicon layer includes a fluoro-alkane gas and an argon gas. The fluoro-alkane includes fully fluoro-substituted alkane (CxFy) and partially fluoro-substituted alkane (CxHyFz). The fully fluoro-substituted alkane can be tetrafluoro-mathane (CF₄), hexafluoro-ethane (C₂F₆), octfluoro-propane (C₃F₈) or octfluoro-butane (C₄F₈), for example. The partially fluoro-substituted alkane (CxHyFz) can be monofluoro-mathane (CH₃F), trifluoro-mathane (CHF₃) or difluoro-methane (CH₂F₂), for example. The fully fluoro-substituted alkane (CxFy) or the partially fluoro-substituted alkane (CxHyFz) can be used alone. Alternatively, the fully fluoro-substituted alkane can be used in combination of the partially fluoro-substituted alkane.

In the case that the fully fluoro-substituted alkane is used in combination of the partially fluoro-substituted alkane, the ratio of the CxHyFz to CxFy is in the range of about 3/1 to about 15/1.

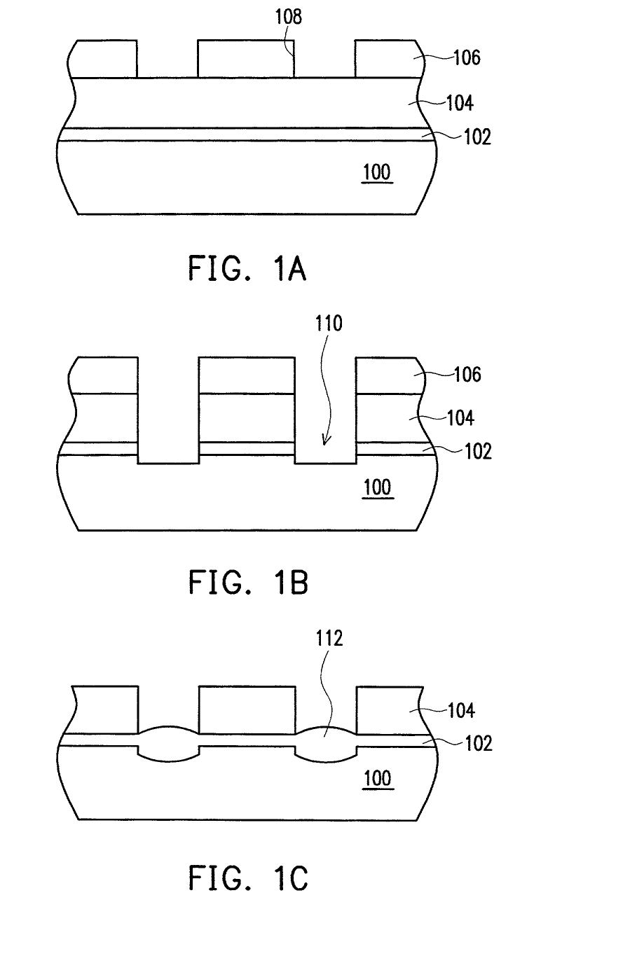

One preferred embodiment of the present invention will be illustrated in detail with reference to FIGS. 1A to 1C.

A substrate 100, such as a silicon substrate, is provided. A pad oxide 102 and a mask layer 104 are formed on the substrate 100. The pad oxide 102 can be formed of silicon oxide by thermal oxidation, for example. The mask layer 104 can be formed of silicon nitride by CVD, for example. Then, a patterned photoresist 106 having an opening 108 is formed on the mask layer 104 to expose part of the mask layer 104.

With reference to FIG. 1B, in an etching device for etching silicon oxide, such as magnetically enhanced reactive ion etching (MERIE), the substrate is subject to an etching process to remove the exposed mask layer 104. An opening 110 is then formed in the underlying pad oxide 102 and the substrate 100.

The etching device can be, for example, a decoupled plasma source (DPS) device, a reactive ion etching (RIE) device, or a down stream etching device.

In the etching process, the plasma etching gas includes a fully fluoro-substituted alkane gas, a partially fluoro-substituted alkane gas, an argon gas and a nitrogen gas. In this embodiment, CxFy can be CF₄ and CxHyFz can be CH₃F. The ratio of CxHyFz/CxFy is about 3/1 to about 15/1. The amount of the nitrogen used is about 1 sccm to about 50 sccm. The amount of the argon used is about 50 sccm to 150 sccm. The etching device is operated under about 110 mtorr to about 200 mtorr of pressure and about 500 w to about 700 w of power.

CF₄ gas can be replaced with hexafluoro-ethane (C₂F₆), octfluoro-propane (C₃F₈) or octfluoro-butane (C₄F₈). CH₃F can be replaced with trifluoro-mathane (CHF₃) or difluoro-methane (CH₂F₂). The fully fluoro-substituted alkane (CxFy) or the partially fluoro-substituted alkane (CxHyFz) can be used alone. Alternatively, the fully fluoro-substituted alkane can be used in combination with the partially fluoro-substituted alkane.

With reference to FIG. 1C, after the photoresist 106 is removed, a field oxide 112 is formed in the bottom of the opening 110 where the substrate 100 is exposed. The formation of the field oxide 112 can be achieved by thermal oxidation, for example.

Table 1 shows etching rate (ER) and the etching uniformity (U%) of nitrogen gas with respect to the silicon oxide and the silicon layer when the nitrogen gas is added in the plasma etching gas. When the flow rate of the nitrogen gas is 0 sccm, that is, the plasma etching gas contains no nitrogen, the etching rate of the silicon layer is 71 and the etching uniformity is 24.31%. When the flow rate of the nitrogen gas added is 10 sccm, the etching rate of the silicon layer is 224 and etching uniformity is 14.5%. When the flow rate of the nitrogen gas added is 30 sccm, the etching rate of the silicon layer is 403 and the etching uniformity is 10.5%. When the flow rate of the nitrogen gas added is 50 sccm, the etching rate of the silicon layer is 520 and the etching uniformity is 7.7%. Therefore, as the flow rate of the nitrogen gas increases, the etching rate of the silicon layer increases and the etching uniformity of the silicon layer decreases. The lower the value of the etching uniformity is, the higher etching uniformity is obtained.

As shown in Table 1, there is little influence on the etching rate and the etching uniformity with respect to the silicon oxide when the nitrogen gas is added in the etching gas.

TABLE 1

| Flow rate of | 0 sccm | | 10 sccm | | 30 sccm | | 50 sccm | |
|---|---|---|---|---|---|---|---|---|
| nitrogen gas | ER | U % | ER | U % | ER | U % | ER | U % |
| Silicon oxide | 2178 | 6.9 | 2526 | 5.7 | 2589 | 5.6 | 2551 | 4.8 |
| Silicon layer | 71 | 24.31 | 224 | 14.5 | 403 | 10.5 | 520 | 7.7 |
| Etching | 30 | | 11.3 | | 6.4 | | 4.9 | |
| selectivity | | | | | | | | |

Therefore, in the present invention, the addition of the nitrogen gas into the plasma etching gas for etching a silicon oxide and a silicon layer can significantly increases the etching uniformity of the silicon layer, while preventing the etching critical dimension from being affected by the overloading of the photoresist.

The plasma etching gas of the present invention is not limited to use for etching the silicon layer. Any other type of silicon layer such as polysilicon, amorphous silicon, doped polysilicon, doped amorphous silicon or doped silicon layer can be also etched using the same. Furthermore, the plasma etching gas of the present invention is not limited to use in forming a field oxide. Any desirable process, such as shallow trench isolation or conductive layer formation, can be performed by using the same.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

What is claimed is:

1. A plasma etching gas suitable for etching a silicon layer in a silicon oxide etching device, the plasma etching gas comprising:
a fluoro-alkane gas; and
a nitrogen gas.

2. The plasma etching gas of claim 1, wherein a flow rate of the nitrogen is about 1 sccm to about 50 sccm.

3. The plasma etching gas of claim 1, wherein the fluoro-alkane is selected from a group consisting of CF₄, C₂F₆, C₃F₈, C₄F₈, CH₃F, CHF₃ and CH₂F₂.

4. The plasma etching gas of claim 1, further comprising an argon gas.

5. The plasma etching gas of claim 4, wherein a flow rate of the argon gas is about 50 sccm to about 150 sccm.

6. A plasma etching gas suitable for etching a silicon layer in a silicon oxide etching device, the plasma etching gas comprising:
a partially fluoro-substituted alkane gas;
a fully fluoro-substituted alkane gas; and
a nitrogen gas.

7. The plasma etching gas of claim 6, wherein a flow rate of the nitrogen is about 1 sccm to about 50 sccm.

8. The plasma etching gas of claim 6, wherein the fully fluoro-substituted alkane is selected from a group consisting of CF₄, C₂F₆, C₃F₈ and C₄F₈.

9. The plasma etching gas of claim 1, wherein the partially fluoro-substituted alkane gas is selected from a group consisting of CH₃F, CHF₃ and CH₂F₂.

10. The plasma etching gas of claim 6, wherein the partially fluoro-substituted alkane gas is CHF₃, and the fully fluoro-substituted alkane gas is CF₄.

11. The plasma etching gas of claim 10, wherein a ratio of CHF₃ to CF₄ is about 3/1 to about 15/1.

12. The plasma etching gas of claim 10, wherein a flow rate of the nitrogen is about 1 sccm to about 50 sccm.

13. The plasma etching gas of claim 10, further comprising an argon gas.

14. The plasma etching gas of claim 13, wherein the flow rate of the argon gas is in the range of about 50 sccm to about 150 sccm.

15. The plasma etching gas of claim 6, wherein a ratio of CHF₃ to CF₄ is about 3/1 to about 15/1.

16. The plasma etching gas of claim 6, further comprising an argon gas.

17. The plasma etching gas of claim 16, wherein flow rate of the argon gas is about 50 sccm to about 150 sccm.

18. A method of producing a semiconductor device, comprising:
providing a substrate;
forming an oxide layer on the substrate;
providing an etching gas consisting of fluoro-alkane gas and nitrogen gas; and
etching the oxide layer by using the etching gas.

19. The method of claim 18, wherein a flow rate of the nitrogen gas is about 1 sccm to about 50 sccm.

20. The method of claim 18, wherein the fluoro-alkane is selected from a group consisting of CF₄, C₂F₆, C₃F₈, C₄F₈, CH₃F, CHF₃ and CH₂F₂.

21. The method of claim 18, wherein the etching gas further comprises an argon gas.

22. The method of claim 21, wherein flow rate of the argon gas is about 50 sccm to about 150 sccm.
